(19) United States
(12) Patent Application Publication
(10) Pub. No.: US 2024/0265883 A1
(43) Pub. Date: Aug. 8, 2024

(54) DISPLAY DEVICE

(71) Applicant: Samsung Display Co., LTD., Yongin-si (KR)

(72) Inventors: SEUNG-JUN LEE, Yongin-si (KR); TAE-HO KIM, Yongin-si (KR); YONGSU LEE, Yongin-si (KR); JAEWOO LEE, Yongin-si (KR); SEUNG-HWAN CHO, Yongin-si (KR)

(21) Appl. No.: 18/498,796

(22) Filed: Oct. 31, 2023

(30) Foreign Application Priority Data
Feb. 6, 2023 (KR) 10-2023-0015809

(51) Int. Cl. G09G 3/3291

(52) U.S. Cl. CPC G09G 3/3291; G09G 2310/0297; G09G 2330/12

(57) ABSTRACT

A display device includes: a demux circuit portion including: a first transistor including a part of a first lower gate pattern, a second transistor including a part of a second lower gate pattern, a first control line connected to the first lower gate pattern and supplying a first lighting test control signal or a first demux control signal, and a second control line connected to the second lower gate pattern and supplying a second lighting test control signal or a second demux control signal, and a lighting circuit portion connected to the demux circuit portion and including: a third transistor including another part of the first lower gate pattern and receiving the first lighting test control signal or the first demux control signal, and a fourth transistor including another part of the second lower gate pattern and receiving the second lighting test control signal or the second demux control signal.

This application claims priority to Korean Patent Application No. 10-2023-0015809 under 35 U.S.C. § 119, filed on Feb. 6, 2023, and all the benefits accruing therefrom under 35 U.S.C. § 119, the content of which in its entirety is herein incorporated by reference.

### BACKGROUND

### 1. Field

Embodiments provide generally to a display device. More particularly, embodiments relate to a display device that provides visual information.

### 2. Description of the Related Art

With a development of information technology, an importance of a display device, which is a connection medium between a user and information, is being highlighted. For example, a use of a display device such as a liquid crystal display device, an organic light-emitting display device, a plasma display device, and the like is increasing.

### SUMMARY

Embodiments provide a display device with reduced dead space.

A display device in embodiments of the disclosure includes a substrate including a display area in which a plurality of sub-pixels is arranged and a non-display area disposed around the display area, a demux circuit portion disposed in the non-display area on the substrate and including: a first switching transistor including a part of a first lower gate pattern, a second switching transistor including a part of a second lower gate pattern, a first control line which is connected to the first lower gate pattern and supplies a first lighting test control signal or a first demux control signal, and a second control line which is connected to the second lower gate pattern and supplies a second lighting test control signal or a second demux control signal, and a lighting circuit portion electrically connected to the demux circuit portion and including: a third switching transistor which includes another part of the first lower gate pattern and receives the first lighting test control signal or the first demux control signal through the first control line and a fourth switching transistor which includes another part of the second lower gate pattern and receives the second lighting test control signal or the second demux control signal through the second control line.

In an embodiment, the lighting circuit portion may include a fifth switching transistor including a part of a third lower gate pattern and a third control line which is connected to the third lower gate pattern and supplies a third lighting test control signal.

In an embodiment, the third lower gate pattern may be spaced apart from the first and second lower gate patterns.

In an embodiment, the demux circuit portion and the lighting circuit portion may share a circuit area in which the third, fourth, and fifth switching transistors are disposed.

In an embodiment, the display device may further include an active layer disposed in the non-display area on the substrate, constituting a semiconductor layer of each of the first, second, third, fourth, and fifth switching transistors, and including: a first active pattern and a second active pattern spaced apart from the first active pattern and including a first part and a second part forming at least an empty space therebetween.

In an embodiment, the first lower gate pattern may partially overlap each of the first active pattern, the first part of the second active pattern, and the second part of the second active pattern. The second lower gate pattern may partially overlap each of the first active pattern, the first part of the second active pattern, and the second part of the second active pattern. The third lower gate pattern may partially overlap the second part of the second active pattern.

In an embodiment, the first switching transistor may further include a part of the first active pattern and a part of the first part of the second active pattern. The second switching transistor may further include another part of the first active pattern and another part of the first part of the second active pattern.

In an embodiment, the third switching transistor may further include a part of the second part of the second active pattern. The fourth switching transistor may further include another part of the second part of the second active pattern. The fifth switching transistor may further include another part of the second part of the second active pattern.

In an embodiment, the lighting circuit portion may further include a first lighting test signal line which is connected to the third switching transistor and supplies a first lighting test signal, a second lighting test signal line which is connected to the fourth switching transistor and supplies a second lighting test signal, and a third lighting test signal line which is connected to the fourth switching transistor and supplies a third lighting test signal.

In an embodiment, the display device may further include a data connection line which is connected to each of the first and second switching transistors and supplies a data voltage, an intermediate bridge pattern connected to the third lighting test signal line through a contact hole, and an upper bridge pattern connected to each of the third lighting test signal line and the data connection line through a contact hole.

In an embodiment, the plurality of sub-pixels may include a blue sub-pixel that emits blue light, a green sub-pixel that emits green light, and a red sub-pixel that emits red light.

In an embodiment, the third switching transistor may transmit the first lighting test signal to the blue sub-pixel in response to the first lighting test control signal. The fourth switching transistor may transmit the second lighting test signal to the green sub-pixel in response to the second lighting test control signal. The fifth switching transistor may transmit the third lighting test signal to the green sub-pixel in response to the third lighting test control signal.

In an embodiment, the first switching transistor may transmit a data voltage to the red sub-pixel and the blue sub-pixel in response to the first demux control signal. The second switching transistor may transmit the data voltage to the green sub-pixel in response to the second demux control signal.

In an embodiment, the lighting circuit portion may be disposed between the display area and the demux circuit portion in a plan view.

In an embodiment, the display device may further include a data driver which is electrically connected to the demux circuit portion and generates a data voltage. The demux circuit portion may divide and output the data voltage to at least two data lines.

A display device in embodiments of the disclosure includes a substrate including a display area in which a plurality of sub-pixels is arranged and a non-display area disposed around the display area, a demux circuit portion disposed in the non-display area on the substrate and including: a first switching transistor, a second switching transistor, a first control line which is connected to the first switching transistor and supplies a first lighting test control signal or a first demux control signal, and a second control line which is connected to the second switching transistor and supplies a second lighting test control signal or a second demux control signal, and a lighting circuit portion electrically connected to the demux circuit portion and including: a third switching transistor that receives the first lighting test control signal or the first demux control signal through the first control line and fourth switching transistor that receives the second lighting test control signal or the second demux control signal through the second control line.

In an embodiment, the lighting circuit portion may include a fifth switching transistor and a third control line which is connected to the fifth switching transistor and supplies a third lighting test control signal.

In an embodiment, the lighting circuit portion may further include a first lighting test signal line which is connected to the third switching transistor and supplies a first lighting test signal, a second lighting test signal line which is connected to the fourth switching transistor and supplies a second lighting test signal, and a third lighting test signal line which is connected to the fourth switching transistor and supplies a third lighting test signal.

In an embodiment, the plurality of sub-pixels may include a blue sub-pixel that emits blue light, a green sub-pixel that emits green light, and a red sub-pixel that emits red light. The third switching transistor may transmit the first lighting test signal to the blue sub-pixel in response to the first lighting test control signal. The fourth switching transistor may transmit the second lighting test signal to the green sub-pixel in response to the second lighting test control signal. The fifth switching transistor may transmit the third lighting test signal to the green sub-pixel in response to the third lighting test control signal.

In an embodiment, the first switching transistor may transmit a data voltage to the red sub-pixel and the blue sub-pixel in response to the first demux control signal. The second switching transistor may transmit the data voltage to the green sub-pixel in response to the second demux control signal.

A display device in embodiments of the disclosure may include a demux circuit portion disposed in a non-display area and that divides and outputs a data voltage to at least two data lines, and a lighting circuit portion electrically connected to the demux circuit portion. Here, the demux circuit portion may include a control line that supplies a lighting test control signal for controlling switching transistors of the lighting circuit portion or a demux control signal for controlling switching transistors of the demux circuit portion. In addition, the demux circuit portion and the lighting circuit portion may share a circuit area in which the switching transistors of the lighting circuit portion are disposed. Accordingly, an area occupied by the lighting circuit portion in the non-display area may be minimized. That is, the dead space of the display device may be reduced.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating an embodiment of a display device according to the disclosure.

FIG. 2 is an equivalent circuit diagram illustrating one sub-pixel disposed in the display area of FIG. 1.

FIG. 3 is a view for explaining circuit configurations of each of a demux circuit portion and a lighting circuit portion of FIG. 1.

FIG. 4 is a cross-sectional view taken along line I-I′ of FIG. 1.

FIG. 5 is an enlarged plan view of area A of FIG. 1.

FIGS. 6, 7, 8, 9, 10, 11, 12, 13, and 14 are plan views illustrating area A of FIG. 5 for each layer.

FIG. 15 is a cross-sectional view taken along line II-II′ of FIG. 5.

FIG. 16 is a cross-sectional view taken along line III-III′ of FIG. 5.

### DETAILED DESCRIPTION

Hereinafter, a display device in embodiments of the disclosure will be explained in detail with reference to the accompanying drawings. The same reference numerals are used for the same components in the drawings, and redundant descriptions of the same components will be omitted.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

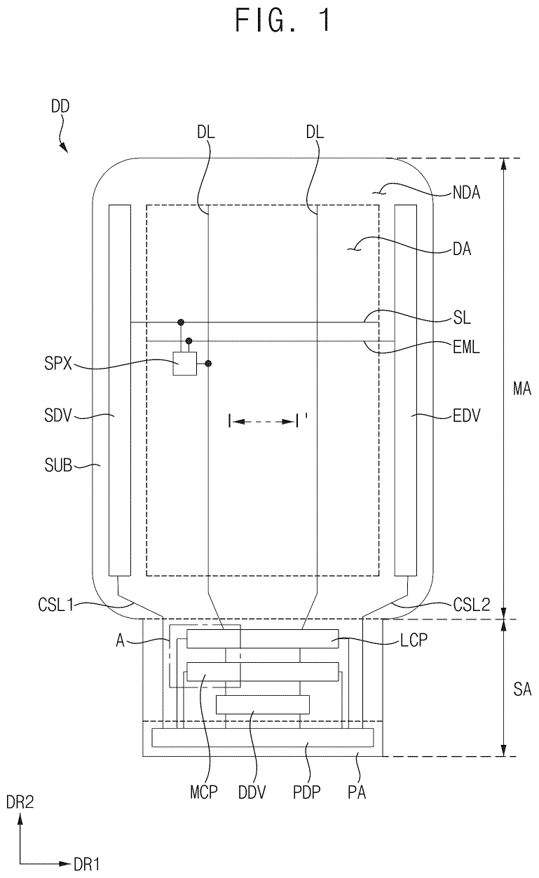

FIG. 1 is a plan view illustrating an embodiment of a display device according to the disclosure.

Referring to FIG. 1, a display device DD in an embodiment may include a substrate SUB, a plurality of sub-pixels SPX, a scan driver SDV, a light-emitting driver EDV, a pad portion PDP, a data driver DDV, a demux circuit portion MCP, and a lighting circuit portion LCP.

The substrate SUB may include a display area DA and a non-display area NDA. The non-display area NDA may be disposed around the display area DA. In an embodiment, the non-display area NDA may surround at least a part of the display area DA, for example. The display area DA may be an area capable of displaying an image by generating light or adjusting transmittance of light provided from an external light source. The non-display area NDA may be an area not displaying an image.

The display area DA and a part of the non-display area NDA may be included in a main area MA. Another part of the non-display area NDA may be included in a sub area SA. The sub area SA may be disposed below the display area DA. In an embodiment, a part of the sub area SA may be bent based on a bending axis extending in a first direction DR1, for example. When the part of the sub area SA is bent based on the bending axis, the sub area SA may at least partially overlap the main area MA in a plan view.

The sub area SA may include a pad area PA. In an embodiment, the pad area PA may have a shape extending along one side of the display device DD, for example. Specifically, the pad area PA may have a shape extending along the first direction DR1 parallel to an upper surface of the substrate SUB.

The plurality of sub-pixels SPX may be disposed in the display area DA on the substrate SUB. Each of the sub-pixels SPX may include a driving element and a light-emitting element electrically connected to the driving element. Each of the sub-pixels SPX may generate light according to a driving signal. The sub-pixels SPX may be entirely arranged in the display area DA in a matrix form.

Drivers for driving the sub-pixels SPX may be disposed in the non-display area NDA on the substrate SUB. In an embodiment, the scan driver SDV, the light-emitting driver EDV, the data driver DDV, and a timing controller may be disposed in the non-display area NDA on the substrate SUB, for example. The timing controller may control the scan driver SDV, the light-emitting driver EDV, and the data driver DDV.

The display device DD may further include a data line DL, a scan line SL, and a light-emitting control line EML disposed in the display area DA on the substrate SUB and connected to the sub-pixels SPX. In addition, the display device DD may further include a first control signal line CSL1 connected to the scan driver SDV and a second control signal line CSL2 connected to the light-emitting driver EDV disposed in the non-display area NDA on the substrate SUB. In an embodiment, each of the data line DL, the scan line SL, and the light-emitting control line EML may be provided in plural, for example.

The scan line SL may be electrically connected to the scan driver SDV and may extend along the first direction DR1. The scan line SL may receive a scan signal from the scan driver SDV and provide the scan signal to the sub-pixels SPX.

The light-emitting control line EML is electrically connected to the light-emitting driver EDV and may extend along the first direction DR1. The light-emitting control line EML may receive a light-emitting signal from the light-emitting driver EDV and provide the light-emitting signal to the sub-pixels SPX. In an embodiment, an active period of the light-emitting signal may be a light-emitting period of the display device DD, and an inactive period of the light-emitting signal may be a non-light-emitting period of the display device DD, for example. The data line DL may be electrically connected to the data driver DDV through the demux circuit portion MCP and the lighting circuit portion LCP, and may extend in a second direction DR2 crossing the first direction DR1. The data line DL may receive the data voltage from the data driver DDV and provide the data voltage to the sub-pixels SPX.

The first control signal line CSL1 may be electrically connected to the pad portion PDP. The first control signal line CSL1 may receive a first control signal from the pad portion PDP and provide the first control signal to the scan driver SDV.

The second control signal line CSL2 may be electrically connected to the pad portion PDP. The second control signal line CSL2 may receive a second control signal from the pad portion PDP and provide the second control signal to the light-emitting driver EDV.

The scan driver SDV may receive the first control signal from the pad portion PDP and generate the scan signal based on the first control signal. The light-emitting driver EDV may receive the second control signal from the pad portion PDP and generate the light-emitting control signal based on the second control signal.

The data driver DDV may be electrically connected to the pad portion PDP and receive a data control signal from the pad portion PDP. The data driver DDV may generate the data voltage based on the data control signal.

The pad portion PDP may be disposed in the pad area PA on the substrate SUB. The pad portion PDP may receive various driving voltages and control signals from the outside. The pad portion PDP may include a plurality of pad electrodes spaced apart from each other along the first direction DR1. In an embodiment, each of the pad electrodes may include metal or a transparent conductive material. In embodiments, the metal that may be used for each of the pad electrodes may include gold (Au), silver (Ag), aluminum (Al), copper (Cu), or the like, for example. In embodiments, the transparent conductive material that may be used for each of the pad electrodes may include indium tin oxide (“ITO”), indium zinc oxide (“IZO”), indium zinc tin oxide (“IZTO”), or the like. Each of these may be used or in any combinations with each other.

The demux circuit portion MCP may be disposed in the sub area SA on the substrate SUB. In an embodiment, the demux circuit portion MCP may be disposed between the data driver DDV and the lighting circuit portion LCP in a plan view, for example. The demux circuit portion MCP may be electrically connected to the data driver DDV and the lighting circuit portion LCP, and divide and output the data voltage supplied from the data driver DDV to the data lines DL. In an embodiment, the demux circuit portion MCP may be a demultiplexer (“DEMUX”).

The lighting circuit portion LCP may be disposed in the sub area SA on the substrate SUB. In an embodiment, the lighting circuit portion LCP may be disposed between the display area DA and the demux circuit portion MCP in the plan view, for example. The lighting circuit portion LCP may be electrically connected to the data line DL. The lighting circuit portion LCP may receive a lighting test control signal and a lighting test signal through the pad portion PDP during a lighting test period, and output the lighting test signal corresponding to the lighting test control signal. Specifically, the lighting circuit portion LCP may include a control line to which a lighting test control signal is supplied, a lighting test signal line to which a lighting test signal is supplied, and a plurality of switching transistors connected to the data lines DL. The lighting test signal output from the lighting circuit portion LCP may be provided to the data lines DL. The lighting circuit portion LCP may inspect whether the sub-pixels SPX are defective.

The lighting circuit portion LCP may maintain an off state by a bias signal supplied from the pad portion PDP during an actual driving period after the lighting test is completed. That is, the lighting circuit portion LCP may be used only before the actual driving period of the display device DD. In other words, during the actual driving period of the display device DD, the lighting test control signal and the lighting test signal may not be supplied to the lighting circuit portion LCP.

FIG. 1 illustrates that the scan driver SDV is disposed in the non-display area NDA adjacent to the left side of the display area DA, and the light-emitting driver EDV is disposed in the non-display area NDA adjacent to the right side of the display area DA, but the embodiments of the disclosure are not limited thereto. In an embodiment, each of the scan driver SDV and the light-emitting driver EDV may be disposed at different positions in the non-display area NDA, for example.

In this specification, a plane may be defined as the first direction DR1 and the second direction DR2 crossing the first direction DR1. In an embodiment, the second direction DR2 may be perpendicular to the first direction DR1, for example.

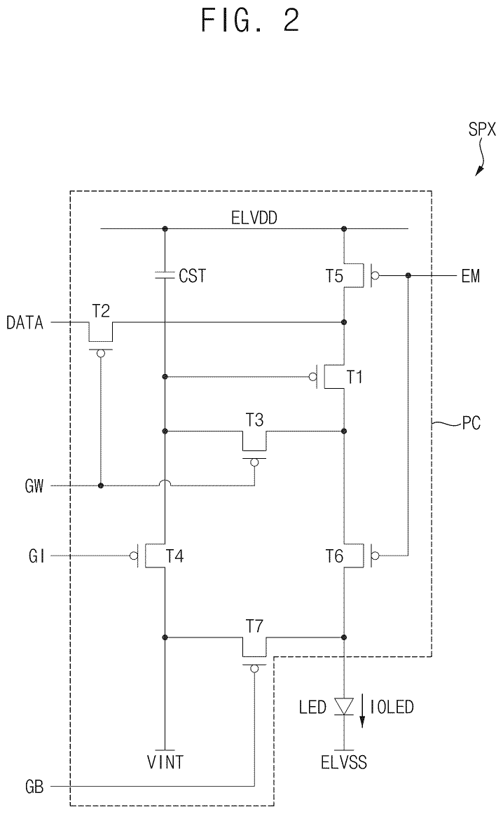

FIG. 2 is an equivalent circuit diagram illustrating one sub-pixel disposed in the display area of FIG. 1.

Referring to FIG. 2, each sub-pixel SPX may include a pixel circuit PC and a light-emitting element LED electrically connected to the pixel circuit PC. The pixel circuit PC may include first, second, third, fourth, fifth, sixth, and seventh transistors T1, T2, T3, T4, T5, T6, and T7 and a storage capacitor CST.

The light-emitting element LED may output light based on a driving current IOLED. The light-emitting element LED may include a first terminal and a second terminal. In an embodiment, the second terminal of the light-emitting element LED may receive a low power supply voltage ELVSS. In an embodiment, the first terminal of the light-emitting element LED may be an anode terminal, and the second terminal of the light-emitting element LED may be a cathode terminal, for example. In an alternative embodiment, the first terminal of the light-emitting element LED may be a cathode terminal, and the second terminal of the light-emitting element LED may be an anode terminal.

The first transistor T1 may include a gate terminal, a first terminal, and a second terminal. In an embodiment, the first terminal of the first transistor T1 may be a source terminal, and the second terminal of the first transistor T1 may be a drain terminal, for example. In an alternative embodiment, the first terminal of the first transistor T1 may be a drain terminal, and the second terminal of the first transistor T1 may be a source terminal. This may be equally applied to the second, third, fourth, fifth, sixth, and seventh transistors T2, T3, T4, T5, T6, and T7 to be described below. Therefore, in the following, descriptions related to this will be omitted.

The first transistor T1 may generate driving current IOLED. In an embodiment, the first transistor T1 may be defined as a driving transistor for driving the sub-pixel SPX. The first transistor T1 may generate the driving current IOLED based on a voltage difference between the gate terminal and the source terminal. In addition, grayscale may be expressed in the sub-pixels SPX based on the magnitude of the driving current IOLED supplied to the light-emitting element LED.

The second transistor T2 may include a gate terminal, a first terminal, and a second terminal. The gate terminal of the second transistor T2 may receive a first scan signal GW. The first terminal of the second transistor T2 may receive a data voltage DATA. The second terminal of the second transistor T2 may be connected to the first terminal of the first transistor T1. The second transistor T2 may be defined as a switching transistor.

The second transistor T2 may supply the data voltage DATA to the first terminal of the first transistor T1 during an activation period of the first scan signal GW. Conversely, the second transistor T2 may block the supply of the data voltage DATA during an inactive period of the first scan signal GW.

The third transistor T3 may include a gate terminal, a first terminal, and a second terminal. The gate terminal of the third transistor T3 may receive the first scan signal GW. The first terminal of the third transistor T3 may be connected to a second terminal of the first transistor T1. The second terminal of the third transistor T3 may be connected to the gate terminal of the first transistor T1.

The fourth transistor T4 may include a gate terminal, a first terminal, and a second terminal. The gate terminal of the fourth transistor T4 may receive a data initialization signal GI. The first terminal of the fourth transistor T4 may receive an initialization voltage VINT. The second terminal of the fourth transistor T4 may be connected to the second terminal of the third transistor T3.

The fourth transistor T4 may supply the initialization voltage VINT to the second terminal of the third transistor T3 during an activation period of the data initialization signal GI. That is, the fourth transistor T4 may initialize the second terminal of the third transistor T3 to the initialization voltage VINT during the activation period of the data initialization signal GI.

The fifth transistor T5 may include a gate terminal, a first terminal, and a second terminal. The gate terminal of the fifth transistor T5 may receive the light-emitting control signal EM. The first terminal of the fifth transistor T5 may receive a high power supply voltage ELVDD. The second terminal of the fifth transistor T5 may be connected to the first terminal of the first transistor T1.

The fifth transistor T5 may supply the high power supply voltage ELVDD to the first terminal of the first transistor T1 during an activation period of the light-emitting control signal EM. Contrary to this, the fifth transistor T5 may block the supply of the high power supply voltage ELVDD during an inactive period of the light-emitting control signal EM.

The sixth transistor T6 may include a gate terminal, a first terminal, and a second terminal. The gate terminal of the sixth transistor T6 may receive the light-emitting control signal EM. The first terminal of the sixth transistor T6 may be connected to a second terminal of the first transistor T1. The second terminal of the sixth transistor T6 may be connected to the first terminal of the light-emitting element LED.

The sixth transistor T6 may supply the driving current IOLED generated by the first transistor T1 to the light-emitting element LED during an activation period of the light-emitting control signal EM. Contrary to this, the sixth transistor T6 may electrically separate the first transistor T1 and the light-emitting element LED from each other during an inactive period of the light-emitting control signal EM.

The seventh transistor T7 may include a gate terminal, a first terminal, and a second terminal. The gate terminal of the seventh transistor T7 may receive a second scan signal GB. The first terminal of the seventh transistor T7 may receive the initialization voltage VINT. The second terminal of the seventh transistor T7 may be connected to the first terminal of the light-emitting element LED.

The seventh transistor T7 may supply the initialization voltage VINT to the first terminal of the light-emitting element LED during an activation period of the second scan signal GB. That is, the seventh transistor T7 may initialize the first terminal of the light-emitting element LED to the initialization voltage VINT during the activation period of the second scan signal GB.

The storage capacitor CST may include a first terminal and a second terminal. The first terminal of the storage capacitor CST may receive the high power supply voltage ELVDD. The second terminal of the storage capacitor CST may be connected to the gate terminal of the first transistor T1.

However, although the pixel circuit PC has been described as including seven transistors and one storage capacitor with reference to FIG. 2, embodiments of the disclosure are not limited thereto. In an embodiment, the pixel circuit PC may have a configuration including at least one transistor and at least one storage capacitor, for example.

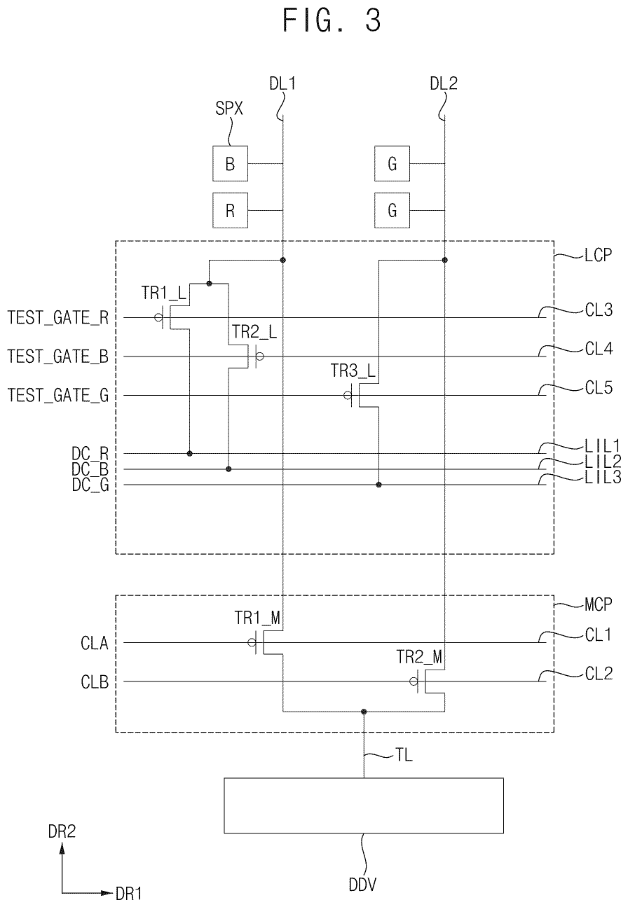

FIG. 3 is a view for explaining circuit configurations of each of a demux circuit portion and a lighting circuit portion of FIG. 1.

Referring to FIGS. 1 and 3, the display device DD may include the demux circuit portion MCP and the lighting circuit portion LCP. The demux circuit portion MCP may be disposed between the data driver DDV and the lighting circuit portion LCP in the plan view, and the lighting circuit portion LCP may be disposed between the demux circuit portion MCP and the display area DA in the plan view.

In FIG. 3, for convenience of description, only some of the sub-pixels SPX disposed in the display area DA are illustrated, and only first and second data lines DL1 and DL2 connected to the sub-pixels SPX are illustrated.

In an embodiment, the sub-pixels SPX may include a red sub-pixel R that emits red light, a green sub-pixel G that emits green light, and a blue sub-pixel B that emits blue light. In an embodiment, the red sub-pixel R and the blue sub-pixel B may be alternately arranged in the same column, and the green sub-pixels G may be arranged in a row in a column adjacent to the column in which the red sub-pixel R and the blue sub-pixel B are arranged, for example. Specifically, the red sub-pixel R and the blue sub-pixel B may be alternately arranged in odd-numbered columns (e.g., a first column), and the green sub-pixel G may be alternately arranged in a row in even-numbered columns (e.g., a second column). The first and second data lines DL1 and DL2 may be disposed in each column.

In an embodiment, the first data line DL1 may be connected to the first column in which the red sub-pixel R and the blue sub-pixel B are alternately arranged, and the second data line DL2 may be connected to the second column in which the green sub-pixel G are arranged in a row.

In FIG. 3, the sub-pixels SPX are illustrated as including only the red sub-pixel R, the green sub-pixel G, and the blue sub-pixel B, but embodiments of the disclosure are not limited thereto. In an embodiment, the sub-pixels SPX may further emit colors other than red, green, and blue, for example.

A transmission line TL may electrically connect the data driver DDV and the first and second data lines DL1 and DL2.

In an embodiment, the demux circuit portion MCP may divide and output the data voltage transmitted through the transmission line TL to the first and second data line DL1 and DL2. In an embodiment, the demux circuit portion MCP may include a plurality of demux circuits, for example. One end of each of the demux circuits may be connected to one transmission line TL, and the other end of each of the demux circuits may be connected to the first data lines DL1 and the second data line DL2.

The demux circuit portion MCP may include a first control line CL1, a second control line CL2, and a plurality of switching transistors.

Each of the first control line CL1 and the second control line CL2 may extend in the first direction DR1. In addition, the first control line CL1 and the second control line CL2 may be spaced apart from each other in the second direction DR2.

The switching transistors of the demux circuit portion MCP may include a first switching transistor TR1_M and a second switching transistor TR2_M. Each of the first switching transistor TR1_M and the second switching transistor TR2_M may be electrically connected to the transmission line TL.

In an embodiment, a gate terminal of the first switching transistor TR1_M may be connected to the first control line CL1 that supplies a first demux control signal CLA, a first terminal of the first switching transistor TR1_M may be connected to the transmission line TL, and a second terminal of the first switching transistor TR1_M may be connected to the first data line DL1, for example. The first switching transistor TR1_M may be turned on by the first demux control signal CLA to connect the transmission line TL and the first data line DL1. That is, the first switching transistor TR1_M may transmit the data voltage to the red sub-pixel R and the blue sub-pixel B in response to the first demux control signal CLA.

In an embodiment, a gate terminal of the second switching transistor TR2_M may be connected to the second control line CL2 that supplies a second demux control signal CLB, a first terminal of the second switching transistor TR2_M may be connected to the transmission line TL, and a second terminal of the second switching transistor TR2_M may be connected to the second data line DL2, for example. The second switching transistor TR2_M may be turned on by the second demux control signal CLB to connect the transmission line TL and the second data line DL2. That is, the second switching transistor TR2_M may transmit the data voltage to the green sub-pixel G in response to the second demux control signal CLB.

In FIG. 3, it has been described as an example that the demux circuit portion MCP includes two switching transistors corresponding to one transmission line TL, but embodiments of the disclosure are not limited thereto. In an embodiment, the demux circuit portion MCP may include three or more switching transistors corresponding to one transmission line TL, for example. In this case, one transmission line TL may be connected to three or more data lines.

In an embodiment, the lighting circuit portion LCP may include a third control line CL3, a fourth control line CL4, a fifth control line CL5, a first lighting test signal line LIL1, a second lighting test LIL2, a third lighting test signal line LIL3, and a plurality of switching transistors.

Each of the third control line CL3, the fourth control line CL4, the fifth control line CL5, the first lighting test signal line LIL1, the second lighting test signal line LIL2, and the third lighting test signal line LIL3 may extend in the first direction DR1. In addition, the third control line CL3, the fourth control line CL4, the fifth control line CL5, the first lighting test signal line LIL1, the second lighting test signal line LIL2, and the third lighting test signal line LIL3 may be space apart from each other in the second direction DR2.

The switching transistors of the lighting circuit portion LCP may include a third switching transistor TR1_L, a fourth switching transistor TR2_L, and a fifth switching transistor TR3_L. Each of the third switching transistor TR1_L and the fourth switching transistor TR2_L may be electrically connected to the first data line DL1, and the fifth switching transistor TR3_L may be electrically connected to the second data line DL2.

In an embodiment, a gate terminal of the third switching transistor TR1_L may be connected to the third control line CL3 that supplies a first lighting test control signal TEST_GATE_R, a first terminal of the third switching transistor TR1_L may be connected to the first lighting test signal line LIL1 that supplies a first lighting test signal DC_R, and a second terminal of the third switching transistor TR1_L may be connected to the first data line DL1, for example. The third switching transistor TR1_L may be turned on by the first lighting test control signal TEST_GATE_R to connect the first lighting test signal line LIL1 and the first data line DL1. That is, the third switching transistor TR1_L may transmit the first lighting test signal DC_R to the red sub-pixel R and the blue sub-pixel B in response to the first lighting test control signal TEST_GATE_R.

In an embodiment, a gate terminal of the fourth switching transistor TR2_L may be connected to the fourth control line CL4 that supplies a second lighting test control signal TEST_GATE_B, a first terminal of the fourth switching transistor TR2_L may be connected to the second lighting test signal line LIL2 that supplies a second lighting test signal DC_B, and a second terminal of the fourth switching transistor TR2_L may be connected to the first data line DL1, for example. The fourth switching transistor TR2_L may be turned on by the second lighting test control signal TEST_GATE_B to connect the second lighting test signal line LIL2 and the first data line DL1. That is, the fourth switching transistor TR2_L may transmit the second lighting test signal DC_B to the red sub-pixel R and the blue sub-pixel B in response to the second lighting test control signal TEST_GATE_B.

In an embodiment, a gate terminal of the fifth switching transistor TR3_L may be connected to the fifth control line CL5 that supplies a third lighting test control signal TEST_GATE_G, a first terminal of the fifth switching transistor TR3_L may be connected to the third lighting test signal line LIL3 that supplies a third lighting test signal DC_G, and a second terminal of the fifth switching transistor TR3_L may be connected to the second data line DL2, for example. The fifth switching transistor TR3_L may be turned on by the third lighting test control signal TEST_GATE_G to connect the third lighting test signal line LIL3 and the second data line DL2. That is, the fifth switching transistor TR3_L may transmit the third lighting test signal DC_G to the green sub-pixel G in response to the third lighting test control signal TEST_GATE_G.

In FIG. 3, for convenience of description, the third, fourth, and fifth switching transistors TR1_L, TR2_L, and TR3_L are illustrated as being included only in the lighting circuit portion LCP, but the disclosure is not limited thereto. In an embodiment, the third, fourth, and fifth switching transistors TR1_L, TR2_L, and TR3_L may also be included in the demux circuit portion MCP. That is, the demux circuit portion MCP and the lighting circuit portion LCP may share a circuit area in which the third, fourth, and fifth switching transistors TR1_L, TR2_L, and TR3_L are disposed. In this case, the third, fourth, and fifth switching transistors TR1_L, TR2_L, and TR3_L are the switching transistors of the lighting circuit portion LCP and are not the switching transistors of the demux circuit portion MCP. A detailed description thereof will be described later.

In addition, in FIG. 3, for convenience of description, the first control line CL1 and the fourth control line CL4 are illustrated as being configured as separate lines and the second control line CL2 and the fifth control line CL5 are illustrated as being configured as separate lines, but the disclosure is not limited thereto. In an embodiment, the first control line CL1 may configure one control line with the fourth control line CL4, and the second control line CL2 may configure one control line with the fifth control line CL5. In this case, the first demux control signal CLA or the second lighting test control signal TEST_GATE_B may be supplied to the first control line CL1, and the second demux control signal CLB or the third lighting test control signal TEST_GATE_G may be supplied to the second control line CL2. A detailed description thereof will be described later.

As described above, the lighting circuit portion LCP may maintain an off state by a bias signal supplied from the pad portion (e.g., the pad unit PDP of FIG. 1) during the actual driving period after the lighting test is completed. That is, during the actual driving period of the display device DD, the lighting test control signal and the lighting test signal may be not supplied to the lighting circuit portion LCP, and the demux circuit portion MCP may receive the demux control signal and the data voltage. Unlike this, during the lighting test period of the display device DD, the lighting circuit portion LCP may receive the lighting test control signal and the lighting test signal, and the demux control signal and the data voltage may be not supplied to the demux circuit portion MCP.

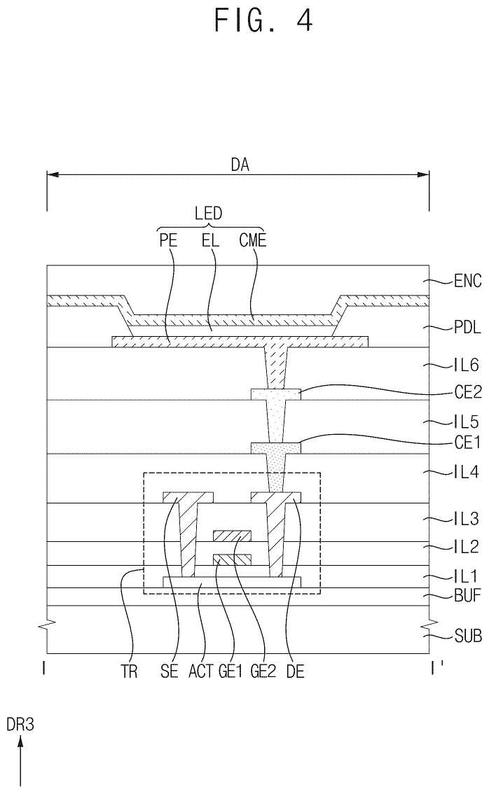

FIG. 4 is a cross-sectional view taken along line I-I′ of FIG. 1. In an embodiment, FIG. 4 is a cross-sectional view illustrating a part of the display area DA of FIG. 1, for example.

Referring to FIG. 4, the display device DD in an embodiment of the disclosure may include a substrate SUB, a buffer layer BUF, a transistor TR, first, second, third, fourth, fifth, and sixth insulating layers IL1, IL2, IL3, IL4, IL5, and IL6, a first connection electrode CE1, a second connection electrode CE2, a pixel defining layer PDL, a light-emitting element LED, and an encapsulation layer ENC.

Here, the transistor TR may include an active pattern ACT, a first gate electrode GE1, a second gate electrode GE2, a source electrode SE, and a drain electrode DE, and the light-emitting element LED may include a pixel electrode PE, a light-emitting layer EL, and a common electrode CME.

As described above, the display device DD may include the display area DA and the non-display area NDA. As the display device DD includes the display area DA and the non-display area NDA, the substrate SUB may include the display area DA and the non-display area NDA.

The substrate SUB may include a transparent material or an opaque material. The substrate SUB may include or consist of a transparent resin substrate. In embodiments, the transparent resin substrate may include polyimide substrates or the like. In this case, the polyimide substrate may include a first organic layer, a first barrier layer, a second organic layer, or the like. In an alternative embodiment, the substrate SUB may include a quartz substrate, a synthetic quartz substrate, a calcium fluoride substrate, an F-doped quartz substrate, a soda-lime glass substrate, a non-alkali glass substrate, or the like. These may be used alone or in any combinations with each other.

The buffer layer BUF may be disposed on the substrate SUB. The buffer layer BUF may prevent diffusion of metal atoms or impurities from the substrate SUB into the transistor TR. In addition, the buffer layer BUF may improve flatness of the surface of the substrate SUB when the surface of the substrate SUB is not uniform. In an embodiment, the buffer layer BUF may include an inorganic material such as silicon oxide, silicon nitride, silicon oxynitride, or the like, for example. These may be used alone or in any combinations with each other.

The active pattern ACT may be disposed on the buffer layer BUF. In an embodiment, the active pattern ACT may include an inorganic semiconductor such as amorphous silicon or polycrystalline silicon or a metal oxide semiconductor. In an embodiment, the active pattern ACT may have a source region, a drain region, and a channel region disposed between the source region and the drain region, for example.

The first insulating layer IL1 may be disposed on the buffer layer BUF. In an embodiment, the first insulating layer IL1 may include an inorganic material such as silicon oxide (SiOₓ), silicon nitride (SiNₓ), silicon carbide (SiCₓ), silicon oxynitride (SiOₓN_{y}), silicon oxycarbide (SiOₓC_{y}), or the like, for example. These may be used alone or in any combinations with each other.

The first gate electrode GE1 may be disposed on the first insulating layer IL1. The first gate electrode GE1 may overlap the channel region of the active pattern ACT. The first gate electrode GE1 may include a metal, an alloy, a metal nitride, a conductive metal oxide, a transparent conductive material, or the like. In embodiments, the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), or the like. In embodiments, the conductive metal oxide may include indium tin oxide, indium zinc oxide, or the like. In addition, embodiments of the metal nitride include aluminum nitride (AlNₓ), tungsten nitride (WNₓ), chromium nitride (CrNₓ), or the like. These may be used individually or in any combinations with each other.

The second insulating layer IL2 may be disposed on the first insulating layer IL1. The second insulating layer IL2 may cover the first gate electrode GE1. In an embodiment, the second insulating layer IL2 may include an inorganic material such as silicon oxide, silicon nitride, silicon oxynitride, or the like, for example. These may be used alone or in any combinations with each other.

The second gate electrode GE2 may be disposed on the second insulating layer IL2. The second gate electrode GE2 may overlap the first gate electrode GE1. In an embodiment, the second gate electrode GE2 may include a metal, an alloy, a metal nitride, a conductive metal oxide, a transparent conductive material, or the like, for example. These may be used alone or in any combinations with each other.

The third insulating layer IL3 may be disposed on the second insulating layer IL2. The third insulating layer IL3 may cover the second gate electrode GE2. In an embodiment, the third insulating layer IL3 may include an inorganic material such as silicon oxide, silicon nitride, silicon oxynitride, or the like, for example. These may be used alone or in any combinations with each other.

The source electrode SE and the drain electrode DE may be disposed on the third insulating layer IL3. The source electrode SE may be connected to the source region of the active pattern ACT through a first contact hole penetrating a first portion of the first, second, and third insulating layers IL1, IL2, and IL3. The drain electrode DE may be connected to the drain region of the active pattern ACT through a second contact hole penetrating a second portion of the first, second, and third insulating layers IL1, IL2, and IL3. In an embodiment, each of the source electrode SE and the drain electrode DE may include a metal, an alloy, a metal nitride, a conductive metal oxide, a transparent conductive material, or the like, for example. These may be used alone or in any combinations with each other.

Accordingly, the transistor TR including the active pattern ACT, the first gate electrode GE1, the second gate electrode GE2, the source electrode SE, and the drain electrode DE may be disposed in the display area DA on the substrate SUB.

The fourth insulating layer IL4 may be disposed on the third insulating layer IL3. The fourth insulating layer IL4 may sufficiently cover the source electrode SE and the drain electrode DE. The fourth insulating layer IL4 may have a substantially flat upper surface. In an embodiment, the fourth insulating layer IL4 may include an organic material such as polyimide resin, polyamide resin, siloxane resin, epoxy resin, or the like, for example. These may be used alone or in any combinations with each other.

The first connection electrode CE1 may be disposed on the fourth insulating layer IL4. The first connection electrode CE1 may be connected to the drain electrode DE through a third contact hole penetrating a part of the fourth insulating layer IL4. In an embodiment, the first connection electrode CE1 may include a metal, an alloy, a metal nitride, a conductive metal oxide, a transparent conductive material, or the like, for example. These may be used alone or in any combinations with each other.

The fifth insulating layer IL5 may be disposed on the fourth insulating layer IL4. The fifth insulating layer IL5 may sufficiently cover the first connection electrode CE1. The fifth insulating layer IL5 may have a substantially flat upper surface. In an embodiment, the fifth insulating layer IL5 may include an organic material such as polyimide resin, polyamide resin, siloxane resin, epoxy resin, or the like, for example. These may be used alone or in any combinations with each other.

The second connection electrode CE2 may be disposed on the fifth insulating layer IL5. The second connection electrode CE2 may be connected to the first connection electrode CE1 through a fourth contact hole penetrating a part of the fifth insulating layer IL5. In an embodiment, the second connection electrode CE2 may include a metal, an alloy, a metal nitride, a conductive metal oxide, a transparent conductive material, or the like, for example. These may be used alone or in any combinations with each other.

The sixth insulating layer IL6 may be disposed on the fifth insulating layer IL5. The sixth insulating layer IL6 may sufficiently cover the second connection electrode CE2. The sixth insulating layer IL6 may have a substantially flat upper surface. In an embodiment, the sixth insulating layer IL6 may include an organic material such as polyimide resin, polyamide resin, siloxane resin, epoxy resin, or the like, for example. These may be used alone or in any combinations with each other.

The pixel electrode PE may be disposed on the sixth insulating layer IL6. The pixel electrode PE may be connected to the second connection electrode CE2 through a fifth contact hole penetrating a part of the sixth insulating layer IL6. In an embodiment, the pixel electrode PE may include a metal, an alloy, a metal nitride, a conductive metal oxide, a transparent conductive material, or the like, for example. These may be used alone or in any combinations with each other. In an embodiment, the pixel electrode PE may function as an anode, for example.

The pixel defining layer PDL may be disposed on the sixth insulating layer IL6. The pixel defining layer PDL may cover an edge of the pixel electrode PE. In an embodiment, the pixel defining layer PDL may include an inorganic material and/or an organic material, for example. In an embodiment, the pixel defining layer PDL may include an organic material such as an epoxy resin, a siloxane resin, or the like. These may be used alone or in any combinations with each other. In another embodiment, the pixel defining layer PDL may include an inorganic material and/or an organic material including or consisting of a light-blocking material such as black pigment, black dye, or the like.

The light-emitting layer EL may be disposed on the pixel electrode PE. The light-emitting layer EL may include an organic material that emits light of a predetermined color. In an embodiment, the light-emitting layer EL may include an organic material that emits at least one of red light, green light, and blue light.

The common electrode CME may be disposed on the pixel defining layer PDL and the light-emitting layer EL. In an embodiment, the common electrode CME may include a metal, an alloy, a metal nitride, a conductive metal oxide, a transparent conductive material, or the like, for example. These may be used alone or in any combinations with each other. In an embodiment, the common electrode CME may operate as a cathode, for example.

Accordingly, the light-emitting element LED including the pixel electrode PE, the light-emitting layer EL, and the common electrode CME may be disposed in the display area DA on the substrate SUB. The light-emitting element LED may be electrically connected to the transistor TR.

The encapsulation layer ENC may be disposed on the common electrode CME. The encapsulation layer ENC may prevent impurities, moisture, air, or the like from permeating the light-emitting element LED from the outside. The encapsulation layer ENC may include at least one inorganic layer and at least one organic layer. In an embodiment, the inorganic layer may include silicon oxide, silicon nitride, silicon oxynitride, or the like, for example. These may be used alone or in any combinations with each other. The organic layer may include a polymer cured material such as polyacrylate or the like.

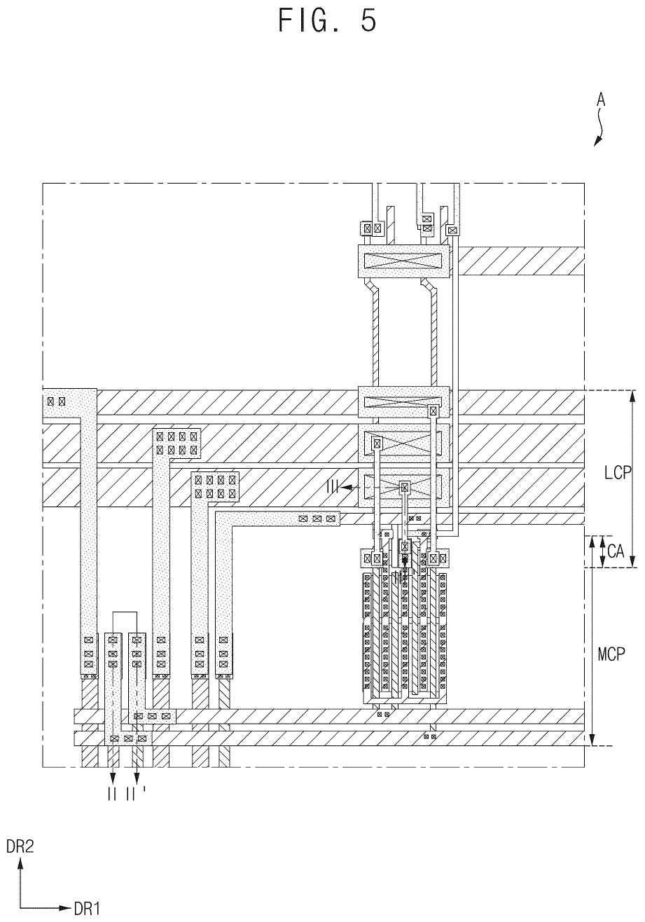

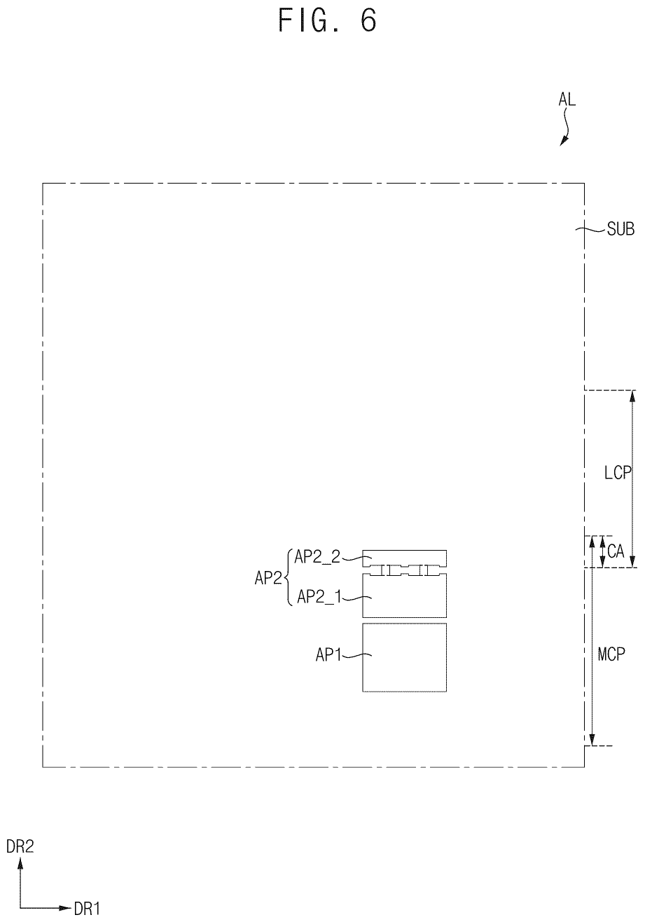

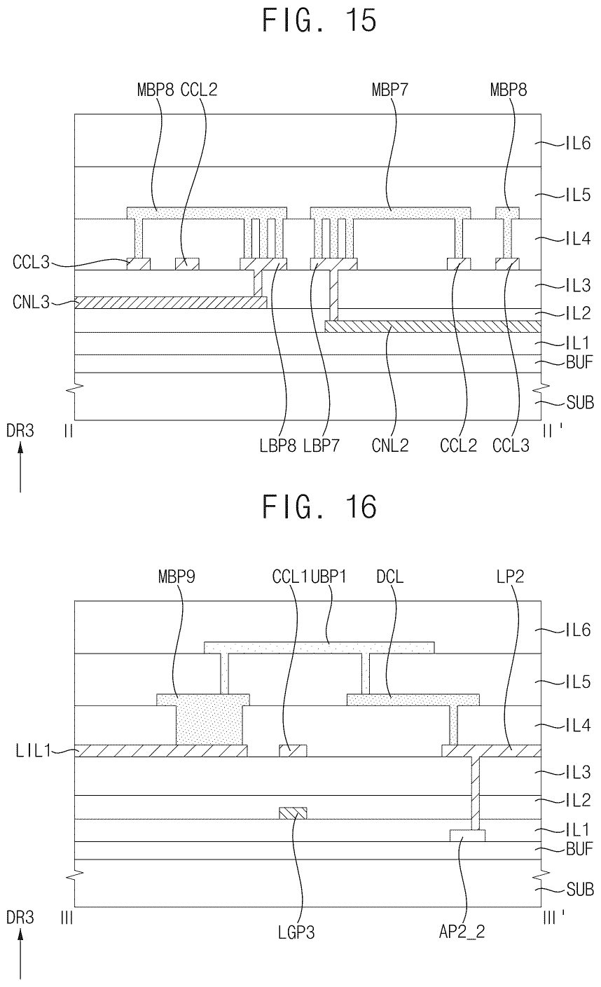

FIG. 5 is an enlarged plan view of area A of FIG. 1. FIGS. 6, 7, 8, 9, 10, 11, 12, 13, and 14 are plan views illustrating area A of FIG. 5 for each layer. FIG. 15 is a cross-sectional view taken along line II-II′ of FIG. 5. FIG. 16 is a cross-sectional view taken along line III-III′ of FIG. 5. In an embodiment, the area A of FIG. 5 is a plan view illustrating configurations of the demux circuit portion MCP and the lighting circuit portion LCP of FIGS. 1 and 3, for example.

Referring to FIGS. 1, 5, and 6, the display device DD in an embodiment of the disclosure may include an active layer AL disposed in the non-display area NDA on the substrate SUB.

The active layer AL may include a first active pattern AP1 and a second active pattern AP2. The first active pattern AP1 and the second active pattern AP2 may include the same material and may be disposed in the same layer. The first active pattern AP1 and the second active pattern AP2 may be spaced apart from each other. In an embodiment, the active layer AL may constitute a semiconductor layer of each of the first, second, third, fourth, and fifth switching transistors TR1_M, TR2_M, TR1_L, TR2_L and TR3_L.

The second active pattern AP2 may include a first part AP2_1 and a second part AP2_2. The first part AP2_1 of the second active pattern AP2 and the second part AP2_2 of the second active pattern AP2 may be connected to each other. In an embodiment, at least an empty space may be formed between the first part AP2_1 of the second active pattern AP2 and the second part AP2_2 of the second active pattern AP2.

In an embodiment, the active layer AL may include a metal oxide semiconductor (e.g., indium gallium zinc oxide (“IGZO”)), an inorganic semiconductor (e.g., amorphous silicon, poly silicon), or an organic semiconductor, for example.

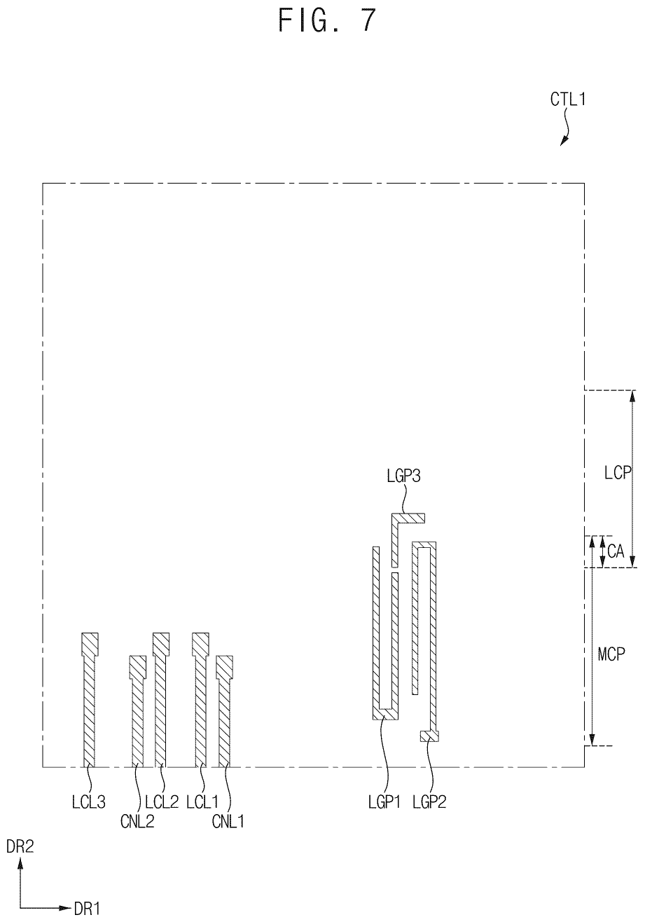

Further referring to FIG. 7, the display device DD in an embodiment may further include a first conductive layer CTL1 disposed in the non-display area NDA. The first conductive layer CTL1 may be disposed on the active layer AL. Specifically, a first insulating layer (e.g., the first insulating layer IL1 of FIG. 4) may be disposed on the active layer AL, and the first conductive layer CTL1 may be disposed on the first insulating layer. That is, the first conductive layer CTL1 may be disposed in the same layer as the first gate electrode GE1 illustrated in FIG. 4 and may include the same material as that of the first gate electrode GE1 illustrated in FIG. 4.

The first conductive layer CTL1 may include first, second, and third lower gate patterns LGP1, LGP2, and LGP3, first, second, and third lower connection lines LCL1, LCL2, and LCL3, and first and second control connection lines CNL1 and CNL2. The first, second, and third lower gate patterns LGP1, LGP2, and LGP3, the first, second, and third lower connection lines LCL1, LCL2, and LCL3, and the first and second control connection lines CNL1 and CNL2 may include the same material and may be disposed in the same layer.

The first, second, and third lower gate patterns LGP1, LGP2, and LGP3, the first, second, and third lower connection lines LCL1, LCL2, and LCL3, and the first and second control connection lines CNL1 and CNL2 may be spaced apart from each other.

The second lower gate pattern LGP2 may be adjacent to the first lower gate pattern LGP1 in the first direction DR1. The third lower gate pattern LGP3 may partially overlap each of the first and second lower gate patterns LGP1 and LGP2 in the first direction DR1. In an embodiment, the third lower gate pattern LGP3 may have an “L” shape planar shape rotated clockwise by about 90 degrees, for example.

The first control connection line CNL1 may extend in the second direction DR2. A first lighting test control signal (e.g., the first lighting test control signal TEST_GATE_R of FIG. 3) may be supplied to the first control connection line CNL1.

The second control connection line CNL2 may extend in the second direction DR2. A second lighting test control signal (e.g., the second lighting test control signal TEST_GATE_B of FIG. 3) or a first demux control signal (e.g., the first demux control signal CLA of FIG. 3) may be supplied to the second control connection line CNL2.

The first lower connection line LCL1 may extend in the second direction DR2. A first lighting test signal (e.g., the first lighting test signal DC_R of FIG. 3) may be supplied to the first lower connection line LCL1.

The second lower connection line LCL2 may extend in the second direction DR2. A second lighting test signal (e.g., the second lighting test signal DC_B of FIG. 3) may be supplied to the second lower connection line LCL2.

The third lower connection line LCL3 may extend in the second direction DR2. A third lighting test signal (e.g., the third lighting test signal DC_G of FIG. 3) may be supplied to the third lower connection line LCL3.

In an embodiment, the first conductive layer CTL1 may include a metal, an alloy, a conductive metal oxide, a transparent conductive material, or the like, for example. These may be used alone or in any combinations with each other.

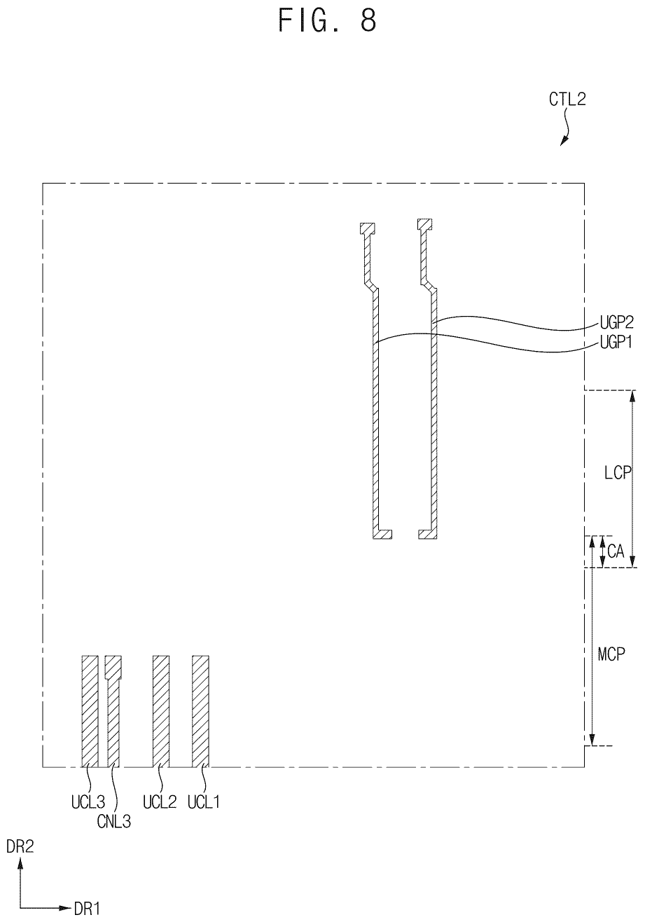

Referring further to FIG. 8, the display device DD in an embodiment may further include a second conductive layer CTL2 disposed in the non-display area NDA. The second conductive layer CTL2 may be disposed on the first conductive layer CTL1. Specifically, a second insulating layer (e.g., the second insulating layer IL2 of FIG. 4) may be disposed on the first conductive layer CTL1, and the second conductive layer CTL2 may be disposed on the second insulating layer. That is, the second conductive layer CTL2 may be disposed in the same layer as the second gate electrode GE2 illustrated in FIG. 4 and may include the same material as that of the second gate electrode GE2 illustrated in FIG. 4.

The second conductive layer CTL2 may include first and second upper gate patterns UGP1 and UGP2, first, second, and third upper connection lines UCL1, UCL2 and UCL3, and a third control connection line CNL3. The first and second upper gate patterns UGP1 and UGP2, the first, second, and third upper connection lines UCL1, UCL2 and UCL3, and the third control connection line CNL3 may include the same material and may be disposed in the same layer.

The first and second upper gate patterns UGP1 and UGP2, the first, second, and third upper connection lines UCL1, UCL2 and UCL3, and the third control connection line CNL3 may be spaced apart from each other.

The first upper gate pattern UGP1 may extend in the second direction DR2. The second upper gate pattern UGP2 may extend in the second direction DR2. The second upper gate pattern UGP2 may be adjacent to the first upper gate pattern UGP1 in the first direction DR1.

The third control connection line CNL3 may extend in the second direction DR2. A third lighting control signal (e.g., the third lighting test control signal TEST_GATE_G of FIG. 3) or a second demux control signal (e.g., the second demux control signal CLB of FIG. 3) may be supplied toe the third control connection line CNL3.

The first upper connection line UCL1 may extend in the second direction DR2. The first lighting test signal may be supplied to the first upper connection line UCL1.

The second upper connection line UCL2 may extend in the second direction DR2. The second lighting test signal may be supplied to the second upper connection line UCL2.

The third upper connection line UCL3 may extend in the second direction DR2. The third lighting test signal may be supplied to the third upper connection line UCL3.

In an embodiment, the second conductive layer CTL2 may include a metal, an alloy, a conductive metal oxide, a transparent conductive material, or the like, for example. These may be used alone or in any combinations with each other.

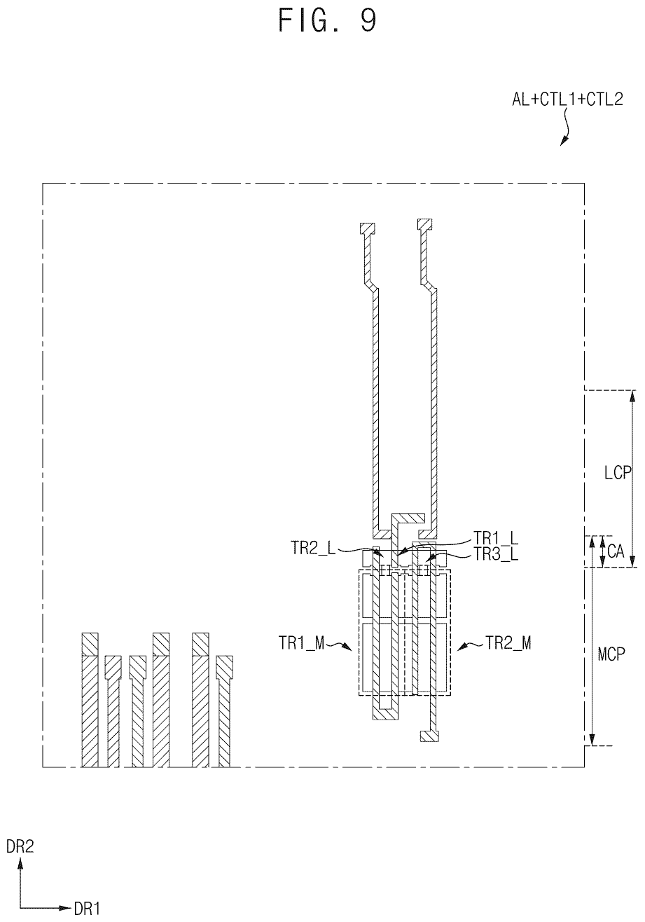

Referring further to FIGS. 6 and 9, the first lower gate pattern LGP1 may partially overlap each of the first active pattern AP1, the first part AP2_1 of the second active pattern AP2, and the second part AP2_2 of the second active pattern AP2. The second lower gate pattern LGP2 may partially overlap each of the first active pattern AP1, the first part AP2_1 of the second active pattern AP2, and the second part AP2_2 of the second active pattern AP2. The third lower gate pattern LGP3 may partially overlap the second part AP2_2 of the second active pattern AP2.

A part (i.e., each part of the first active pattern AP1 and the first part AP2_1 of the second active pattern AP2) of the active layer AL may constitute the first switching transistor TR1_M together with a part (i.e., a gate terminal) of the first lower gate pattern LGP1 overlapping the first active pattern AP and the first part AP2_1 of the second active pattern AP2.

Another part (i.e., each another part of the first active pattern AP1 and the first part AP2_1 of the second active pattern AP2) of the active layer AL may constitute the second switching transistor TR2_M together with a part (i.e., a gate terminal) of the second lower gate pattern LGP2 overlapping the first active pattern AP1 and the first part AP2_1 of the second active pattern AP2.

A part of the second part AP2_2 of the second active pattern AP2 may constitute the third switching transistor TR1_L together with a part (i.e., a gate terminal) of the third lower gate pattern LGP3 overlapping the second part AP2_2 of the second active pattern AP2.

Another part of the second part AP2_2 of the second active pattern AP2 may constitute the fourth switching transistor TR2_L together with a part (i.e., a gate terminal) of the first lower gate pattern LGP1 overlapping the second part AP2_2 of the second active pattern AP2.

Another part of the second part AP2_2 of the second active pattern AP2 may constitute the fifth switching transistor TR3_L together with a part (i.e., a gate terminal) of the second lower gate pattern LGP2 overlapping the second part AP2_2 of the second active pattern AP2.

In an embodiment, the demux circuit portion MCP may include the first switching transistor TR1_M, the second switching transistor TR2_M, the third switching transistor TR1_L, the fourth switching transistor TR2_L, and the fifth switching transistor TR3_L. The lighting circuit portion LCP may include the third switching transistor TR1_L, the fourth switching transistor TR2_L, and the fifth switching transistor TR3_L. In other words, the demux circuit portion MCP and the lighting circuit portion LCP may share a circuit area CA in which the third, fourth, and fifth switching transistors TR1_L, TR2_L, and TR3_L are disposed.

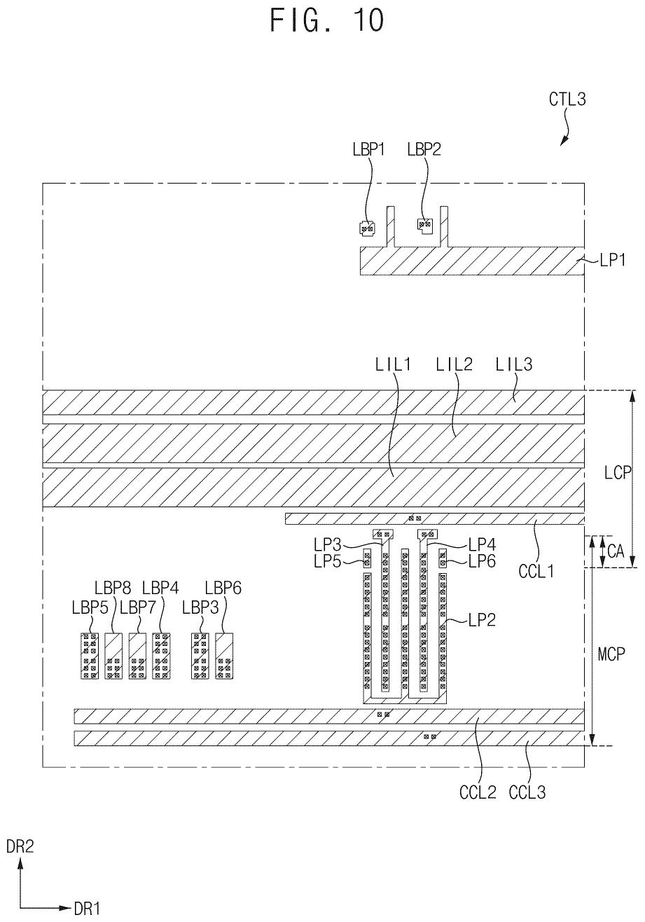

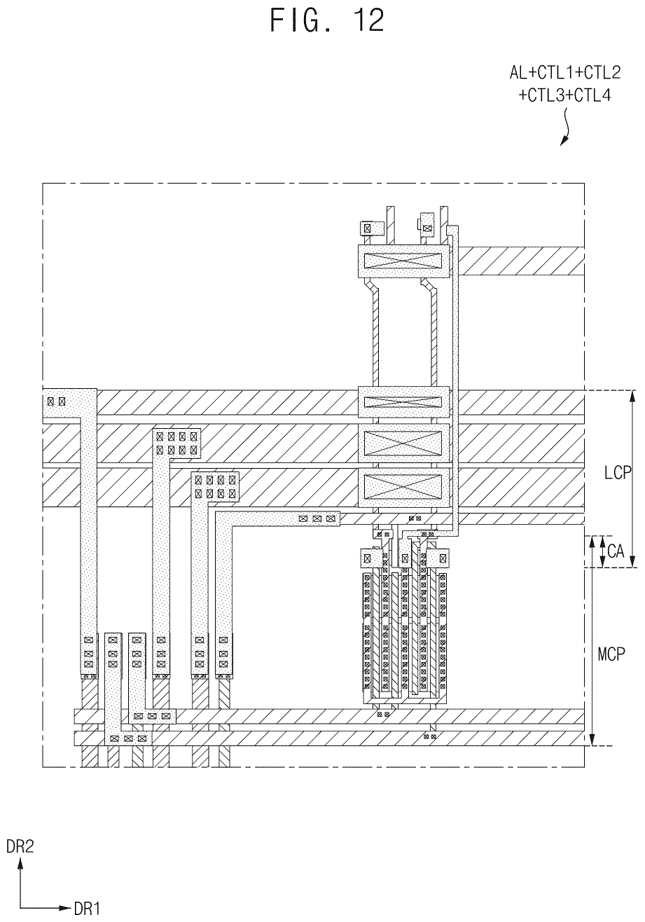

Further referring to FIGS. 10 and 12, the display device DD in an embodiment may further include a third conductive layer CTL3 disposed in the non-display area NDA. The third conductive layer CTL3 may be disposed on the second conductive layer CTL2. Specifically, a third insulating layer (e.g., the third insulating layer IL3 of FIG. 4) may be disposed on the second conductive layer CTL2, and the third conductive layer CTL3 may be disposed on the third insulating layer. That is, the third conductive layer CTL3 may be disposed in the same layer as the source electrode SE and the drain electrode DE illustrated in FIG. 4 and may include the same material as that of the source electrode SE and the drain electrode DE illustrated in FIG. 4.

The third conductive layer CTL3 may include first, second, third, fourth, fifth, and sixth lower patterns LP1, LP2, LP3, LP4, LP5, and LP6, first, second, third, fourth, fifth, sixth, seventh, and eighth lower bridge patterns LBP1, LBP2, LBP3, LBP4, LBP5, LBP6, LBP7, and LBP8, first, second, and third lighting test signal lines LIL1, LIL2, and LIL3, and first, second, and third control lines CCL1, CCL2, and CCL3.

The first, second, third, fourth, fifth, and sixth lower patterns LP1, LP2, LP3, LP4, LP5, and LP6, the first, second, third, fourth, fifth, sixth, seventh, and eighth lower bridge patterns LBP1, LBP2, LBP3, LBP4, LBP5, LBP6, LBP7, and LBP8, the first, second, and third lighting test signal lines LIL1, LIL2, and LIL3, and the first, second, and third control lines CCL1, CCL2, and CCL3 may include the same material and may be disposed in the same layer.

The first, second, third, fourth, fifth, and sixth lower patterns LP1, LP2, LP3, LP4, LP5, and LP6, the first, second, third, fourth, fifth, sixth, seventh, and eighth lower bridge patterns LBP1, LBP2, LBP3, LBP4, LBP5, LBP6, LBP7, and LBP8, the first, second, and third lighting test signal lines LIL1, LIL2, and LIL3, and the first, second, and third control lines CCL1, CCL2, and CCL3 may be spaced apart from each other.

The first lighting test signal line LIL1 may extend in the first direction DR1. The first lighting test signal may be supplied to the first lighting test signal line LIL1.

The second lighting test signal line LIL2 may extend in the first direction DR1. The second lighting test signal may be supplied to the second lighting test signal line LIL2.

The third lighting test signal line LIL3 may extend in the first direction DR1. The third lighting test signal line LIL3 may be disposed between the first and second lighting test signal lines LIL1 and LIL2. The third lighting test signal may be supplied to the third lighting test signal line LIL3.

The first lower pattern LP1 may extend in the first direction DR1. A high power supply voltage (e.g., the high power supply voltage ELVDD of FIG. 2) may be supplied to the first lower pattern LP1.

In an embodiment, the second lower pattern LP2 may have an “E” shape planar shape rotated by about 90 degrees in a counterclockwise direction, for example. The second lower pattern LP2 may be connected to the first and second active patterns AP1 and AP2 through contact holes (refer to FIG. 16).

The third lower pattern LP3 may extend in the second direction DR2. The third lower pattern LP3 may be connected to the first and second active patterns AP1 and AP2 and the first upper gate pattern UGP1 through contact holes.

The fourth lower pattern LP4 may extend in the second direction DR2. The fourth lower pattern LP4 may be connected to the first and second active patterns AP1 and AP2 and the second upper gate pattern UGP2 through contact holes.

The fifth lower pattern LP5 may be connected to the second part AP2_2 of the second active pattern AP2 through contact holes.

The sixth lower pattern LP6 may be connected to the second part AP2_2 of the second active pattern AP2 through contact holes.

The first lower bridge pattern LBP1 may be connected to the first upper gate pattern UGP1 through contact holes. The second lower bridge pattern LBP2 may be connected to the second upper gate pattern UGP2 through contact holes.

The third lower bridge pattern LBP3 may be respectively connected to the first lower connection line LCL1 and the first upper connection line UCL1 through contact holes. The fourth lower bridge pattern LBP4 may be respectively connected to the second lower connection line LCL2 and the second upper connection line UCL2 through contact holes. The fifth lower bridge pattern LBP5 may be respectively connected to the third lower connection line LCL3 and the third upper connection line UCL3 through contact holes.

The sixth lower bridge pattern LBP6 may be connected to the first control connection line CNL1 through contact holes. The seventh lower bridge pattern LBP7 may be connected to the second control connection line CNL2 through contact holes (refer to FIG. 15). The eighth lower bridge pattern LBP8 may be connected to the third control connection line CNL3 through contact holes (refer to FIG. 15).

The first control line CCL1 may extend in the first direction DR1. The first control line CCL1 may be connected to the third lower gate pattern LGP3 through contact holes. The first lighting test control signal may be supplied to the first control line CCL1. Accordingly, the first control line CCL1 may be connected to the third switching transistor TR1_L, and the first control line CCL1 may supply the first lighting test control signal to the third lower gate pattern LGP3.

The second control line CCL2 may extend in the first direction DR1. The second control line CCL2 may be connected to the first lower gate pattern LGP1 through contact holes. In an embodiment, the second lighting test control signal or the first demux control signal may be supplied to the second control line CCL2. Accordingly, the second control line CCL2 may be connected to the second switching transistor TR2_M and the fourth switching transistor TR2_L, and the second control line CCL2 may supply the second lighting test control signal or the first demux control signal to the first lower gate pattern LGP1.

The third control line CCL3 may extend in the first direction DR1. The third control line CCL3 may be connected to the second lower gate pattern LGP2 through contact holes. In an embodiment, the third lighting test control signal or the second demux control signal may be supplied to the third control line CCL3. Accordingly, the third control line CCL3 may be connected to the second switching transistor TR2_M and the fifth switching transistor TR3_L, and the third control line CCL3 may supply the third lighting test control signal or the second demux control signal to the second lower gate pattern LGP2.

In an embodiment, the demux circuit portion MCP may further include the second control line CCL2 and the third control line CCL3, and the lighting circuit portion LCP may include the first lighting test signal line LIL1, the second lighting test signal line LIL2, the third lighting test signal line LIL3, and the first control line CCL1.

In an embodiment, the third conductive layer CTL3 may include a metal, an alloy, a conductive metal oxide, a transparent conductive material, or the like, for example. These may be used alone or in any combinations with each other.

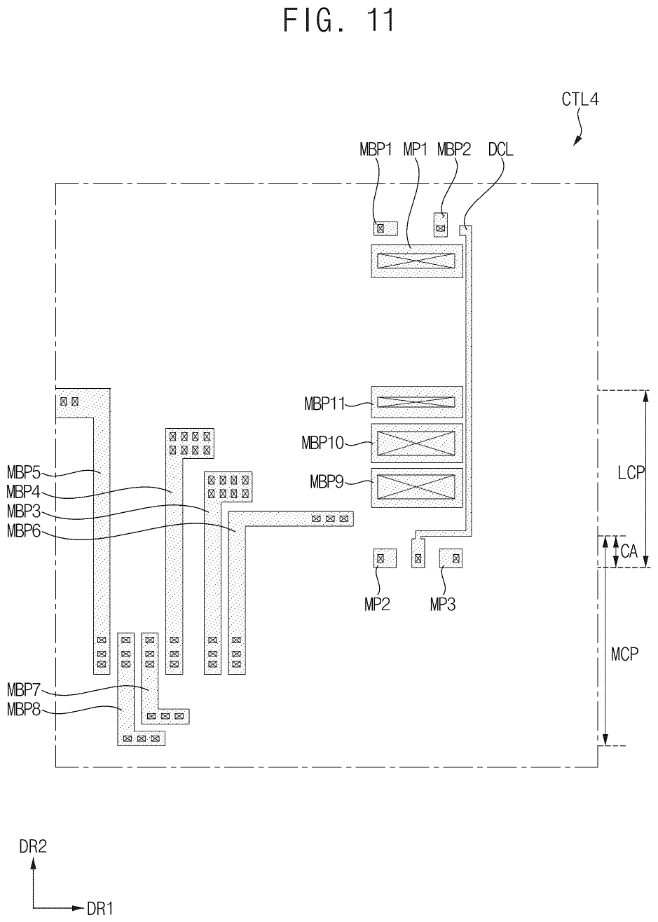

Referring further to FIG. 11, the display device DD in an embodiment may further include a fourth conductive layer CTL4 disposed in the non-display area NDA. The fourth conductive layer CTL4 may be disposed on the third conductive layer CTL3. Specifically, a fourth insulating layer (e.g., the fourth insulating layer IL4 of FIG. 4) may be disposed on the third conductive layer CTL3, and the fourth conductive layer CTL4 may be disposed on the fourth insulating layer. That is, the fourth conductive layer CTL4 may be disposed in the same layer as the first connection electrode CE1 illustrated in FIG. 4 and may include the same material as that of the first connection electrode CE1 illustrated in FIG. 4.

The fourth conductive layer CTL4 may include data connection line DCL, first, second, and third intermediate patterns MP1, MP2, and MP3, and first, second, third, fourth, fifth, sixth, seventh, eighth, ninth, tenth, and eleventh intermediate bridge patterns MBP1, MBP2, MBP3, MBP4, MBP5, MBP6, MBP7, MBP8, MBP9, MBP10, and MBP11. The data connection line DCL, the first, second, and third intermediate patterns MP1, MP2, and MP3, and the first, second, third, fourth, fifth, sixth, seventh, eighth, ninth, tenth, and eleventh intermediate bridge patterns MBP1, MBP2, MBP3, MBP4, MBP5, MBP6, MBP7, MBP8, MBP9, MBP10, and MBP11 may include the same material and may be disposed in the same layer.

The data connection line DCL, the first, second, and third intermediate patterns MP1, MP2, and MP3, and the first, second, third, fourth, fifth, sixth, seventh, eighth, ninth, tenth, and eleventh intermediate bridge patterns MBP1, MBP2, MBP3, MBP4, MBP5, MBP6, MBP7, MBP8, MBP9, MBP10, and MBP11 may be spaced apart from each other.

The data connection line DCL may extend in the second direction DR2. The data connection line DCL may be connected to the second lower pattern LP2 through a contact hole (refer to FIG. 16). Accordingly, the data connection line DCL may be electrically connected to the third and fourth switching transistors TR1_L and TR2_L. The data voltage may be supplied to the data connection line DCL.

The first intermediate pattern MP1 may be connected to the first lower pattern LP1 through a contact hole. The second intermediate pattern MP2 may be connected to the fifth lower pattern LP5 through a contact hole. The third intermediate pattern MP3 may be connected to the sixth lower pattern LP6 through a contact hole.

The first intermediate bridge pattern MBP1 may be connected to the first lower bridge pattern LBP1 through a contact hole. The second intermediate bridge pattern MBP2 may be connected to the second lower bridge pattern LBP2 through a contact hole.

The third intermediate bridge pattern MBP3 may connect the first lighting test signal line LIL1 and the third lower bridge pattern LBP3 through contact holes. Accordingly, the first lighting test signal may be supplied to the first lighting test signal line LIL1 through the first lower connection line LCL1, the first upper connection line UCL1, and the third lower bridge pattern LBP3.

The fourth intermediate bridge pattern MBP4 may connect the second lighting test signal line LIL2 and the fourth lower bridge pattern LBP4 through contact holes. Accordingly, the second lighting test signal may be supplied to the second lighting test signal line LIL2 through the second lower connection line LCL2, the second upper connection line UCL2, and the fourth lower bridge pattern LBP4.

The fifth intermediate bridge pattern MBP5 may connect the third lighting test signal line LIL3 and the fifth lower bridge pattern LBP5 through contact holes. Accordingly, the third lighting test signal may be supplied to the third lighting test signal line LIL3 through the third lower connection line LCL3, the third upper connection line UCL3, and the fifth lower bridge pattern LBP5.

The sixth intermediate bridge pattern MBP6 may connect the first control connection line CNL1 and the first control line CCL1 through contact holes. Accordingly, the first lighting test control signal may be supplied to the first control line CCL1 through the first control connection line CNL1 and the sixth intermediate bridge pattern MBP6.

The seventh intermediate bridge pattern MBP7 may connect the second control line CCL2 and the seventh lower bridge pattern LBP7 through contact holes (refer to FIG. 15). Accordingly, the second lighting test control signal or the first demux control signal may be supplied to the second control line CCL2 through the second control connection line CNL2, the seventh lower bridge pattern LBP7, and the seventh intermediate bridge pattern MBP7.

The eighth intermediate bridge pattern MBP8 may connect the third control line CCL3 and the eighth lower bridge pattern LBP8 through contact holes (refer to FIG. 15). Accordingly, the third lighting test control signal or the second demux control signal may be supplied to the third control line CCL3 through the third control connection line CNL3, the eighth lower bridge pattern LBP8, and the eighth intermediate bridge pattern MBP8.

The ninth intermediate bridge pattern MBP9 may be connected to the first lighting test signal line LIL1 through a contact hole (refer to FIG. 16). The tenth intermediate bridge pattern MBP10 may be connected to the second lighting test signal line LIL2 through a contact hole. The eleventh intermediate bridge pattern MBP11 may be connected to the third lighting test signal line LIL3 through a contact hole.

In an embodiment, the fourth conductive layer CTL4 may include a metal, an alloy, a conductive metal oxide, a transparent conductive material, or the like, for example. These may be used alone or in any combinations with each other.

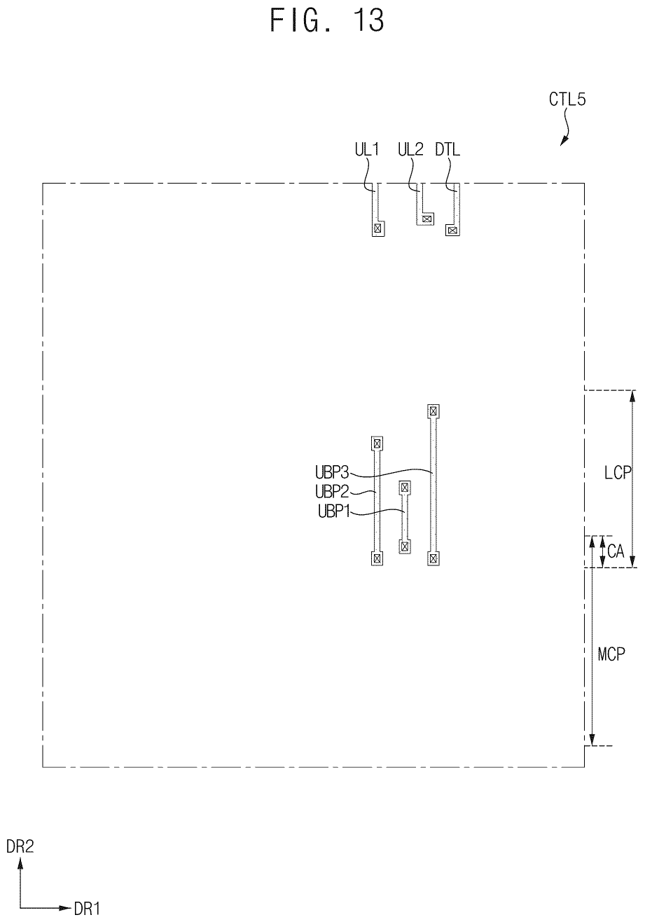

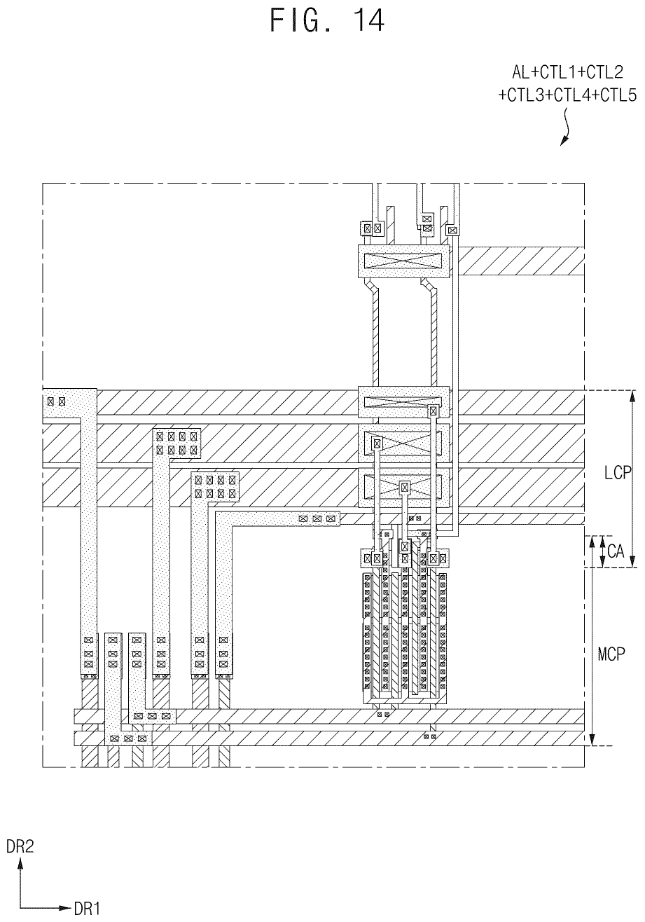

Referring to FIGS. 13 and 14, the display device DD in an embodiment may further include a fifth conductive layer CTL5 disposed in the non-display area NDA. The fifth conductive layer CTL5 may be disposed on the fourth conductive layer CTL4. Specifically, a fifth insulating layer (e.g., the fifth insulating layer IL5 of FIG. 4) may be disposed on the fourth conductive layer CTL4, and the fifth conductive layer CTL5 may be disposed on the fifth insulating layer. That is, the fifth conductive layer CTL5 may be disposed in the same layer as the second connection electrode CE2 illustrated in FIG. 4 and may include the same material as that of the second connection electrode CE2 illustrated in FIG. 4.

The fifth conductive layer CTL5 may include a data transfer line DTL, first and second upper lines UL1 and UL2, and first, second, and third upper bridge patterns UBP1, UBP2, and UBP3. The data transfer line DTL, the first and second upper lines UL1 and UL2, and the first, second, and third upper bridge patterns UBP1, UBP2, and UBP3 may include the same material and may be disposed in the same layer.

The data transfer line DTL, the first and second upper lines UL1 and UL2, and the first, second, and third upper bridge patterns UBP1, UBP2, and UBP3 may be spaced apart from each other.

The data transfer line DTL may extend in the second direction DR2. The data transfer line DTL may be connected to the data connection line DCL through a contact hole. The data voltage may be supplied to the data transfer line DTL. The data transfer line DTL may correspond to or be connected to the transmission line TL of FIG. 3.

Each of the first and second upper lines UL1 and UL2 may extend in the second direction DR2. The first upper line UL1 may be connected to the first intermediate bridge pattern MBP1 through a contact hole. The second upper line UL2 may be connected to the second intermediate bridge pattern MBP2 through a contact hole. The first and second upper lines UL1 and UL2 may respectively correspond to the first and second data lines DL1 and DL2 of FIG. 3 or be connected to the first and second data lines DL1 and DL2 of FIG. 3.

The first upper bridge pattern UBP1 may extend in the second direction DR2. The first upper bridge pattern UBP1 may connect the data connection line DCL and the ninth intermediate bridge pattern MBP9 through contact holes (refer to FIG. 16). Accordingly, the first lighting test signal line LIL1 may be connected to the third switching transistor TR1_L.

The second upper bridge pattern UBP2 may extend in the second direction DR2. The second upper bridge pattern UBP2 may connect the second intermediate pattern MP2 and the tenth intermediate bridge pattern MBP10 through contact holes. Accordingly, the second lighting test signal line LIL2 may be connected to the fourth switching transistor TR2_L.

The third upper bridge pattern UBP3 may extend in the second direction DR2. The third upper bridge pattern UBP3 may connect the third intermediate pattern MP3 and the eleventh intermediate bridge pattern MBP11 through contact holes. Accordingly, the third lighting test signal line LIL3 may be connected to the fifth switching transistor TR3_L.

Accordingly, the first and second lighting test signals or the data voltage may be supplied to the first upper gate pattern UGP1 and the first upper line UL1 through the first upper bridge pattern UBP1. In addition, the third lighting test signal or the data voltage may be supplied to the second upper gate pattern UGP2 and the second upper line UL2 through the second upper bridge pattern UBP2.

The display device DD in embodiments of the disclosure may include the demux circuit portion MCP disposed in the non-display area NDA and that divides and outputs the data voltage to at least two data lines, and the lighting circuit portion LCP electrically connected to the demux circuit portion MCP. Here, the demux circuit portion MCP may include a control line (e.g., the second control line CCL2 and the third control line CCL3) that supplies a lighting test control signal for controlling switching transistors of the lighting circuit portion or a demux control signal for controlling switching transistors of the demux circuit portion. In addition, the demux circuit portion MCP and the lighting circuit portion LCP may share the circuit area CA in which the switching transistors of the lighting circuit portion LCP are disposed. Accordingly, an area occupied by the lighting circuit portion LCP in the non-display area NDA may be minimized. That is, the dead space of the display device DD may be reduced.

The disclosure may be applied to various display devices. In an embodiment, the disclosure is applicable to various display devices such as display devices for vehicles, ships and aircraft, portable communication devices, display devices for exhibition or information transmission, medical display devices, or the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the inventive concept. Accordingly, all such modifications are intended to be included within the scope of the inventive concept as defined in the claims. Therefore, it is to be understood that the foregoing is illustrative of various embodiments and is not to be construed as limited to the illustrative embodiments disclosed, and that modifications to the disclosed embodiments, as well as other embodiments, are intended to be included within the scope of the appended claims.

What is claimed is:

1. A display device comprising:
a substrate including:
a display area in which a plurality of sub-pixels is arranged; and
a non-display area disposed around the display area;
a demux circuit portion disposed in the non-display area on the substrate and including:
a first switching transistor including a part of a first lower gate pattern;
a second switching transistor including a part of a second lower gate pattern;
a first control line which is connected to the first lower gate pattern and supplies a first lighting test control signal or a first demux control signal; and
a second control line which is connected to the second lower gate pattern and supplies a second lighting test control signal or a second demux control signal; and
a lighting circuit portion electrically connected to the demux circuit portion and including:
a third switching transistor which includes another part of the first lower gate pattern and receives the first lighting test control signal or the first demux control signal through the first control line; and
a fourth switching transistor which includes another part of the second lower gate pattern and receives the second lighting test control signal or the second demux control signal through the second control line.

2. The display device of claim 1, wherein the lighting circuit portion includes:
a fifth switching transistor including a part of a third lower gate pattern; and
a third control line which is connected to the third lower gate pattern and supplies a third lighting test control signal.

3. The display device of claim 2, wherein the third lower gate pattern is spaced apart from the first and second lower gate patterns.

4. The display device of claim 2, wherein the demux circuit portion and the lighting circuit portion share a circuit area in which the third, fourth, and fifth switching transistors are disposed.

5. The display device of claim 2, further comprising:
an active layer disposed in the non-display area on the substrate, constituting a semiconductor layer of each of the first, second, third, fourth, and fifth switching transistors, and including: a first active pattern and a second active pattern spaced apart from the first active pattern and including a first part and a second part forming at least an empty space therebetween.

6. The display device of claim 5, wherein the first lower gate pattern partially overlaps each of the first active pattern, the first part of the second active pattern, and the second part of the second active pattern,
the second lower gate pattern partially overlaps each of the first active pattern, the first part of the second active pattern, and the second part of the second active pattern, and
the third lower gate pattern partially overlaps the second part of the second active pattern.

7. The display device of claim 6, wherein the first switching transistor further includes a part of the first active pattern and a part of the first part of the second active pattern, and
the second switching transistor further includes another part of the first active pattern and another part of the first part of the second active pattern.

8. The display device of claim 6, wherein the third switching transistor further includes a part of the second part of the second active pattern,
the fourth switching transistor further includes another part of the second part of the second active pattern, and
the fifth switching transistor further includes another part of the second part of the second active pattern.

9. The display device of claim 2, wherein the lighting circuit portion further includes:
a first lighting test signal line which is connected to the third switching transistor and supplies a first lighting test signal;
a second lighting test signal line which is connected to the fourth switching transistor and supplies a second lighting test signal; and
a third lighting test signal line which is connected to the fourth switching transistor and supplies a third lighting test signal.

10. The display device of claim 9, further comprising:
a data connection line which is connected to each of the first and second switching transistors and supplies a data voltage;
an intermediate bridge pattern connected to the third lighting test signal line through a contact hole; and
an upper bridge pattern connected to each of the third lighting test signal line and the data connection line through a contact hole.

11. The display device of claim 9, wherein the plurality of sub-pixels includes:
a blue sub-pixel which emits blue light;
a green sub-pixel which emits green light; and
a red sub-pixel which emits red light.

12. The display device of claim 11, wherein the third switching transistor transmits the first lighting test signal to the blue sub-pixel in response to the first lighting test control signal,
the fourth switching transistor transmits the second lighting test signal to the green sub-pixel in response to the second lighting test control signal, and
the fifth switching transistor transmits the third lighting test signal to the green sub-pixel in response to the third lighting test control signal.

13. The display device of claim 11, wherein the first switching transistor transmits a data voltage to the red sub-pixel and the blue sub-pixel in response to the first demux control signal, and
the second switching transistor transmits the data voltage to the green sub-pixel in response to the second demux control signal.

14. The display device of claim 1, wherein the lighting circuit portion is disposed between the display area and the demux circuit portion in a plan view.

15. The display device of claim 1, further comprising:
a data driver which is electrically connected to the demux circuit portion and generates a data voltage,
wherein the demux circuit portion divides and outputs the data voltage to at least two data lines.

16. A display device comprising:
a substrate including:
a display area in which a plurality of sub-pixels is arranged; and
a non-display area disposed around the display area;
a demux circuit portion disposed in the non-display area on the substrate and including:
a first switching transistor;
a second switching transistor;
a first control line which is connected to the first switching transistor and supplies a first lighting test control signal or a first demux control signal; and
a second control line which is connected to the second switching transistor and supplies a second lighting test control signal or a second demux control signal; and
a lighting circuit portion electrically connected to the demux circuit portion and including:
a third switching transistor which receives the first lighting test control signal or the first demux control signal through the first control line; and
a fourth switching transistor which receives the second lighting test control signal or the second demux control signal through the second control line.

17. The display device of claim 16, wherein the lighting circuit portion includes:
a fifth switching transistor; and
a third control line which is connected to the fifth switching transistor and supplies a third lighting test control signal.

18. The display device of claim 17, wherein the lighting circuit portion further includes:
a first lighting test signal line which is connected to the third switching transistor and supplies a first lighting test signal;
a second lighting test signal line which is connected to the fourth switching transistor and supplies a second lighting test signal; and
a third lighting test signal line which is connected to the fourth switching transistor and supplies a third lighting test signal.

19. The display device of claim 18, wherein the plurality of sub-pixels includes:
a blue sub-pixel which emits blue light;
a green sub-pixel which emits green light; and
a red sub-pixel which emits red light, and
wherein the third switching transistor transmits the first lighting test signal to the blue sub-pixel in response to the first lighting test control signal,
the fourth switching transistor transmits the second lighting test signal to the green sub-pixel in response to the second lighting test control signal, and
the fifth switching transistor transmits the third lighting test signal to the green sub-pixel in response to the third lighting test control signal.

20. The display device of claim 19, wherein the first switching transistor transmits a data voltage to the red sub-pixel and the blue sub-pixel in response to the first demux control signal, and
the second switching transistor transmits the data voltage to the green sub-pixel in response to the second demux control signal.
